(19) United States
(12) Patent Application Publication
(10) Pub. No.: US 2022/0077338 A1
(43) Pub. Date: Mar. 10, 2022

(54) SEMI-TRANSPARENT MULTI-CELL PHOTOVOLTAIC MODULE SUBJECTED TO RECURRENT PERIPHERAL SHADE

(71) Applicant: Garmin Switzerland GmbH, Schaffhausen (CH)

(72) Inventors: Xavier Noël, Grenoble (FR); Mathieu Borg, Lambesc (FR)

(21) Appl. No.: 17/455,123

(22) Filed: Nov. 16, 2021

Related U.S. Application Data
(63) Continuation of application No. PCT/IB2019/054054, filed on May 16, 2019.

(51) Int. Cl. H01L 31/0468; H01L 31/0465

(52) U.S. Cl. CPC H01L 31/0468; H01L 31/0465

(57) ABSTRACT

A semi-transparent photovoltaic module made up of a plurality of photovoltaic cells that are electrically connected in series, said cells being composed of active photovoltaic regions (2) contained in annuli referred to as active annuli, said active photovoltaic regions of a given active annulus being separated by insulating regions (4); and of vacant space (3) that forms transparent regions in transparent annuli; two adjacent annuli being separated by one transparent annulus (3) and two active photovoltaic regions (2) of adjacent active annuli belonging to the same cell being connected by at least one conductive bridge interconnect (8). Said module is characterized in that adjacent insulating regions (4) do not face each other.

### RELATED APPLICATIONS

The present application is a continuation of, and claims priority benefit to, co-pending international application entitled, “SEMI-TRANSPARENT MULTI-CELL PHOTOVOLTAIC MODULE SUBJECTED TO RECURRENT PERIPHERAL SHADE,” International Application No. PCT/IB2019/054054, filed May 16, 2019, which is hereby incorporated by reference into the current application in its entirety.

### BACKGROUND

The present invention relates to the field of semi-transparent thin-film photovoltaic modules having a multi-cell architecture and subjected to peripheral shade effects intrinsic to the device with which they are associated. These modules are intended to produce electrical energy and/or to function as photovoltaic sensors or transducers.

A thin-film photovoltaic cell is composed of at least one substrate, a first transparent electrode, a second generally metallic electrode and an absorber layer. The term “thin-film” is understood to mean photovoltaic layers of any nature (organic, inorganic), the thickness of the absorber of which does not exceed ten micrometers.

A thin-film photovoltaic module is made up of a multitude of thin-film photovoltaic cells. Generally, it is composed of a plurality of photovoltaic cells that are arranged in series in order to increase the electric voltage across the terminals of the module. Methods are known for placing photovoltaic cells in series through successive stages of isolation and interconnection of the various constituent layers of the thin-film photovoltaic module, as described in document EP0500451-B1.

A thin-film photovoltaic cell semi-transparent to visible light may comprise a plurality of opaque active photovoltaic regions that are separated by transparent regions. The photovoltaic regions can be of any shape and size such that the human eye cannot distinguish them. To do this, the width of the photovoltaic regions is preferably less than 200 micrometers. In a known embodiment, the active photovoltaic regions and the transparent regions are organized in networks of elementary, linear, circular or polygonal geometric structures. The transparency of the photovoltaic cell is a function of the surface fraction that is occupied by the active opaque photovoltaic regions. Patent WO2014/188092-A1 presents an embodiment of a semitransparent thin-film photovoltaic monocell. In an advantageous embodiment, the transparent regions are arranged in the transparent electrode in addition to the metal electrode and the absorber in order to increase the transmission of light at the transparent regions, since by reducing the number of interfaces, the optical phenomena of reflections at the interfaces are minimized.

It is known to those skilled in the art that the electric power generated by a photovoltaic module can be greatly reduced compared to the optimum energy production conditions, in particular during partial or total shade of all or part of the photovoltaic cells making up a photovoltaic module. Semi-transparent photovoltaic modules are subject to the same type of constraints. In particular, shading part of a semi-transparent photovoltaic module whose semi-transparent cells are all connected in series drastically impacts the power-voltage curve, even if a very small part of the module or cell is shaded. Indeed, in a series architecture, the current is the same in all the cells. For example, if a single cell is shaded and experiences a 25% current loss, then the current generated by the module also suffers the same loss.

### BRIEF DESCRIPTION OF THE DRAWING FIGURES

FIG. 1A is a diagram showing an annulus in the shape of a flower.

FIG. 1B is a diagram showing a ring-shaped annulus.

FIG. 1C is a diagram showing a ring-shaped annulus split into two annulus arcs by two insulating regions.

FIG. 2A is a diagram representing a semi-transparent photovoltaic module intended to be integrated into a watch of circular geometry.

FIG. 2B is a diagram showing a watch having a recurring flange generating permanent shade at the periphery of the photovoltaic module.

FIG. 3A is an example of a semi-transparent photovoltaic module composed of a single cell, the circular active photovoltaic regions of which are electrically connected to each other by bridge interconnects.

FIGS. 3B and 3C are schematics of a semi-transparent photovoltaic module based on the same architecture as FIG. 3A, to which insulating regions have been added (placed in straight or curved lines) to form four cells whose active surfaces are equal.

FIGS. 4A, 4B, and 4C are block diagrams showing the four arcs of circles of the first and of the second radius of the structure according to embodiments of the invention.

In all of the figures, two axes (X) and (Y) forming an orthonormal coordinate system are shown in order to facilitate their geometric description.

### DETAILED DESCRIPTION

Embodiments of the invention provide a semi-transparent photovoltaic module composed of a multitude of semi-transparent thin-film cells connected in series and exhibiting an improved visual quality of the cells when they are subjected to the effects of recurrent or even permanent shade.

One feature is a semi-transparent photovoltaic module made up of a multitude of semi-transparent thin-film cells connected in series and subjected to recurrent or even permanent shade effects, whereof the active regions, the transparent regions, and the bridge interconnects between active regions are placed so that the insulation lines and the bridge interconnects are less visible, or even invisible to the naked eye for an observer placed a few centimeters from the photovoltaic surface.

In some implementations, a watch provided with such a photovoltaic module, and a glazing provided with such a photovoltaic module.

In the remainder of the document, the term “annulus” refers to a continuous region of defined thickness, constant or not, forming a closed line around a central point. For example, a ring is an annulus with circular symmetry. An annulus is characterized by:
its interior line, defined as the smallest closed line composing it;
its exterior line, defined as the largest closed line composing it;
its central point;
its width defined at a point as the smallest distance between the interior line and the exterior line.

A ring is therefore defined by its central point, which is the center C, its interior line corresponding to the minimum radius Rₘᵢₙ and its exterior line corresponding to the maximum radius Rₘₐₓ. In the case of a ring, the width is constant; it is defined as the smallest distance separating the minimum radius Rₘᵢₙ from the maximum radius Rₘₐₓ of the ring.

An annulus is formed from one or more materials. According to the invention, an annulus consists mainly of active materials forming active regions, advantageously active photovoltaic regions. Spaces that are not active regions will be designated by the term “vacant space.” These vacant spaces have the particularity of not being electrically conductive.

An insulating region is defined as a space forming an electrical discontinuity within the active surfaces belonging to the same annulus. This insulating region electrically insulates the adjacent active regions.

The term “annulus arc” is used to define a continuous portion of said annulus. This annulus arc is defined for example by its center, its interior line, its exterior line, its starting angle Âd and its stopping angle Âa with respect to a reference position. For example, a ring arc is therefore defined by its center, its radius Rₘᵢₙ, its radius Rₘₐₓ, its starting angle Âd and its stopping angle Âa.

In the remainder of the document, semi-transparent photovoltaic modules will be considered. The vacant spaces correspond to the transparent regions.

Standardizing the integration of photovoltaic modules generates new problems. In the case of integrating semi-transparent modules into watches, it is advantageous to use the same module design regardless of the configuration of the flange of the watches (in order to reduce the production costs of said modules). The flange that forms the junction between the dial and the watch glass, depending on its design, may be more or less wide, more or less transparent, which generates different shade effects depending on said design. In the remainder of this document, the term “recurring flange” is used to refer to any device causing a permanent shade effect on the semi-transparent photovoltaic module integrated in a system such as a watch.

One feature of the invention is to make the inter-cell separations, more commonly called insulation lines, invisible to the naked eye, even for circular geometry modules, which are notably suitable for the manufacture of solar watches in particular.

According to the invention, a semi-transparent photovoltaic module consists of a plurality of photovoltaic cells electrically connected in series. Said cells are composed of:
active photovoltaic regions contained in annuli called active annuli, said active photovoltaic regions of the same active annulus being separated by insulating regions;
vacant spaces forming transparent regions according to transparent annuli;
two adjacent active annuli being separated by a transparent annulus and two active photovoltaic regions of adjacent active annuli belonging to the same cell being connected by at least one conductive bridge interconnect.

Said cells are characterized in that the portions of adjacent insulating regions do not face each other.

Advantageously, the conductive bridge interconnects do not face one another either.

In order to increase transparency, the insulating region portions are transparent.

Preferably, the active annuli are all of the same geometric nature.

For example, for applications using a semi-transparent photovoltaic module integrated into electronic devices with a circular geometry such as watches, it is recommended that the active annuli and the transparent annuli be concentric rings. In order to resolve the problem of watch flanges generating partial shade of the photovoltaic module, it is desirable for the active annuli to be radially spaced by a constant pitch Pₐ and for them to have a constant width.

Advantageously, the annulus is only composed of active photovoltaic regions.

Advantageously, the active photovoltaic regions are of the same width as the active annuli and have a constant width CD. In order for these active regions to be imperceptible to the eye, the width of the active regions will ideally be between 10 nm and 50 μm. Advantageously, the active photovoltaic regions are included in the active annuli, but the active annulus can be made up of active regions and non-active regions.

In order to minimize the addition of material and to make the bridge interconnects invisible, it is desirable for the length of the bridge interconnects to be equal to Pₐ-CD. In order not to create a visual disturbance between the network of concentric rings and the network of bridge interconnects, it is necessary for the width of the concentric rings and the width of the bridge interconnects to be of the same order of magnitude. Advantageously, said widths are equal. Furthermore, in order not to create an ordered network of bridge interconnects that would be detectable with the naked eye, the bridge interconnects are distributed randomly between two active photovoltaic regions of adjacent active annuli belonging to the same cell.

Advantageously, the total area of all the bridge interconnects does not exceed 10% of the total area of all active regions of the photovoltaic module.

In order to increase the efficiency of the photovoltaic module, the bridge interconnects are formed of thin layers identical to the active photovoltaic regions so that said bridges are not only conductors, but also convert the light energy received.

In order to produce the architecture of such a photovoltaic module, the method for designing the semi-transparent photovoltaic module comprises the following steps:

1. Create a working file or image;

2. Choose the initial parameters;

3. Calculate the length of the annulus arcs;

4. Calculate the starting angles;

5. Calculate the stopping angles;

6. Draw the annulus arcs from the pre-calculated parameters;

7. Determine the placement bounds of the bridge interconnects;

8. Choose the placement of the bridge interconnects;

9. Trace the bridge interconnects.
An annulus arc of index (i,Rₖ) is defined by its mean radius (Rₖ), its width (CD), its starting angle (Âd_{i,R_k}) and its arc length (L_{arc_k}).
The angle Âd_{1,R_k} is an angle measured in radians, the value of which is chosen randomly between 0 and 2 n/N.
For any integer k ranging from 1 to the total number (NB) of annuli, the condition (Âd_{1,R_k}≠Âd_{1,R_k-1}) and (Âd_{1,R_k}≠Âd_{1,R_k+1}) for k>1 is verified.
for any integer k ranging from 1 to NB and any integer i ranging from 1 to N, the stopping angle of the trace of the arc of circle of index (i,Rₖ) is calculated according to: Âa_{i,R_k}=Âd_{i+1,R_k}−θₖ where θₖ corresponds to the angle measured in radians associated with the inter-arc length and associated with the ring of mean radius Rₖ. This angle is defined by the relation: θₖ=L_{inter_arc}/Rₖ.
the choice of bounds delimiting the placement of the bridge interconnects is defined according to the following sub-steps:
   Define the interval I₁ by I₁=[Âd_{1,R_k+1}=Âa_{1,R_k+1}]
   Find the two values among the Âd_{i,R_k} and Âa_{i,R_k} for i varying from 1 to N which belong to the interval I₁, where Âₘᵢₙ is the smaller of these two values and Âₘₐₓ is the larger,
      If Âₘᵢₙ and Âₘₐₓ have the same index, they are the two bounds delimiting the placement of the bridge interconnects.
      Otherwise, we find the index i of the arc of radius Rₖ and the two bounds of the maximum difference Â_{diff} such that Â_{diff}=Max((Âₘᵢₙ−Âd_{1,R_k+1}), (Âa_{1,R_k+1}−Âₘₐₓ)). This index i therefore defines the annulus arc of radius Rₖ that optimizes the maximum of bridge interconnects between the annulus arc of radius Rₖ₊₁ and index 1 and the annulus arc of radius Rₖ and index i. The two bounds of the difference, either Âₘᵢₙ and Âd_{1,R_k+1} or Âa_{1,R_k+1} and Âₘₐₓ, are the two bounds delimiting the placement of the bridge interconnects.

Advantageously, the placement of the bridge interconnects is random within the bounds delimiting the placement of said bridge interconnects.

The photovoltaic module according to the invention, in particular in its circular geometry form, fits perfectly into electronic devices such as watches without being drastically affected by their flange.

This type of photovoltaic module according to the invention can also be integrated into any semi-transparent support such as a glazing, for example.

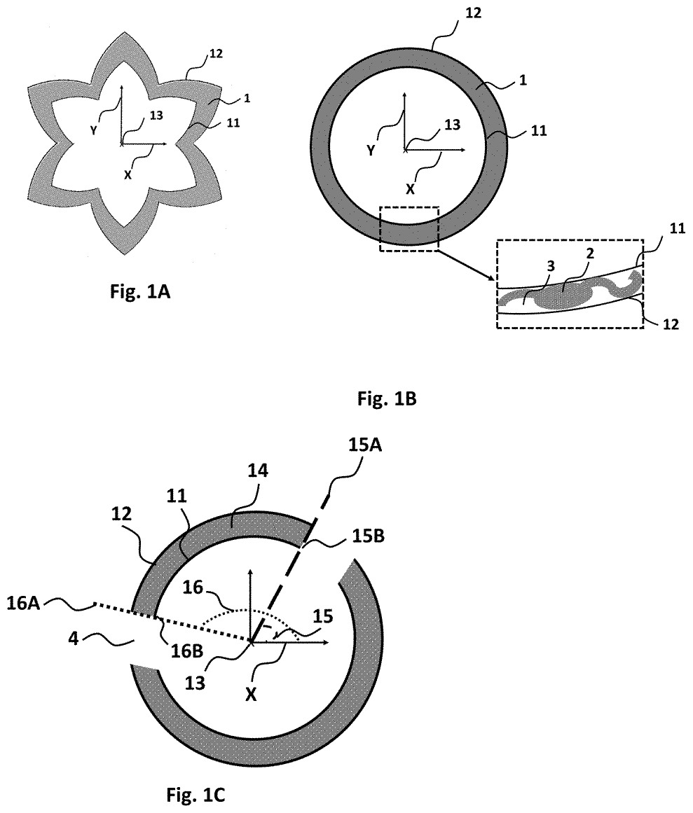

FIG. 1A is a diagram showing an annulus (1) in the shape of a flower. The annulus is defined by:
its interior line (11), defined as the smallest closed line composing it;
its exterior line (12), defined as the largest closed line composing it;
its central point (13), which is the center of symmetry of the geometric figure, and which also embodies the origin of the orthonormal coordinate system (X; Y).
   In this particular case, the annulus does not have a constant width.

FIG. 1B is a diagram showing a ring-shaped annulus (1) defined by:
its interior line (11), corresponding to a circle of minimum radius Rₘᵢₙ;
its exterior line (12), corresponding to a circle of maximum radius Rₘₐₓ;
Its central point (13), corresponding to the center of the circles of radii Rₘᵢₙ and Rₘₐₓ.

Unlike the case of FIG. 1A, the annulus has a constant width. The annulus (1) is made of one or more materials. According to the invention, all or part of an annulus (1) consists of active materials forming active regions (2), advantageously active photovoltaic regions. When the annulus is not exclusively made up of the active regions (2), it presents vacant spaces (3), which are electrically non-conductive regions which may or may not be transparent.

FIG. 1C is a diagram showing a ring-shaped annulus split into two annulus arcs (14) by two insulating regions (4). An insulating region (4) is defined as a space forming an electrical discontinuity within the active regions belonging to the same annulus. This insulating region electrically insulates said active regions from the annulus. In the illustrated case, the annulus arcs (14) are ring arcs. A ring arc is characterized by its center (13), its arc of circle with radius Rₘᵢₙ (11), its arc of circle with radius Rₘₐₓ (12), its starting angle (15) and its stopping angle (16). Its starting angle Âd (15) is defined as the angle counted positively (according to the convention of trigonometry) going from the (X) axis to the starting ray (15A) which originates in the center (13) and which intercepts the first end (15B) of the annulus arc (14). Its angle of arrival Aa (16) is defined as the angle counted positively going from the (X) axis to the arrival ray (16A) which originates in the center (13) and which intercepts the second end of the arc (16B).

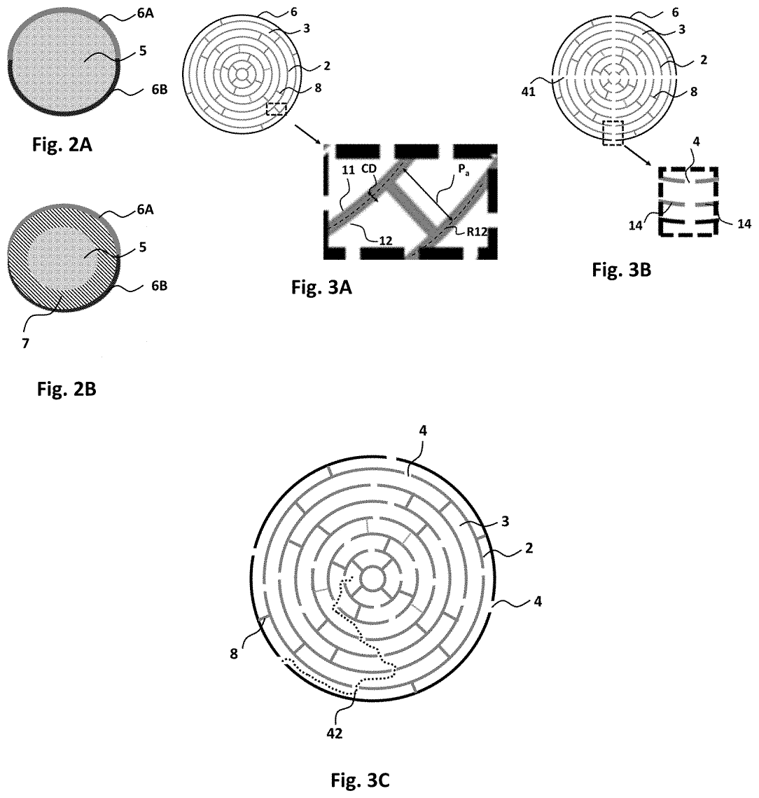

FIG. 2A is a diagram showing a semi-transparent photovoltaic module (5) intended to be integrated into a watch of circular geometry. Front (6A) and rear (6B) contact buses are arranged at the end of the semi-transparent active regions. The case of a watch having a recurring flange generating permanent shade (7) at the periphery of the photovoltaic module is shown in FIG. 2B.

In order to simplify FIG. 3A, 3B, 3C, the front and rear contact buses are not shown. Only the location (6) of these buses is embodied at the end of the modules. Those skilled in the art will know how to place them suitably depending on the architecture of the modules.

FIG. 3A is an example of architecture known from the state of the art of a single photovoltaic cell with circular geometry and whose active photovoltaic regions (2), in the form of concentric rings, are electrically connected to one another by a plurality of bridge interconnects (8). Bridge interconnects (8) are conductive elements allowing charges (electrons and holes) to circulate between the active rings (2) in order to be collected at the buses (6). When not transparent, bridge interconnects (8) are preferably made of the same materials as those composing the rings (2) so as to generate current by photovoltaic effect.

The active photovoltaic regions (2) are separated by vacant spaces (3), which are transparent regions also in the form of rings. These transparent regions are openings made at least in the non-transparent materials constituting the active regions (metal electrode and absorber) in order to allow a maximum of light to pass. Advantageously, these openings are also provided in the transparent electrode. In this example, the active photovoltaic regions (2) have the same dimensions as the active annuli (1) shown in FIG. 1B.

In this example, the width CD (acronym for “critical dimension”) of the active photovoltaic regions (2) is defined as the difference between the radius Rₘₐₓ of the circle (12) and the radius Rₘᵢₙ of the circle (11). Advantageously, this width is constant within the same ring. Preferably, all the active photovoltaic regions (2) have the same width. The latter is advantageously between 10 nm and 50 μm, which allows the network of active annuli to be imperceptible to the human eye. The line (R12) is defined equidistant from the interior (12) and exterior (11) lines. In the case of a ring, this line (R12) embodies the circle of mean radius R of the ring, such that R=(Rₘₐₓ+Rₘᵢₙ)/2. The pitch Pₐ of the ring network is defined as the minimum distance between two mean radii R of adjacent rings. The pitch Pₐ of the active annuli can be different from the pitch Pt of the transparent annuli, in particular when the width CD is not constant. In the case of FIG. 3A, Pₐ=Pt. The length L of the bridge interconnects (8) is defined as the length of the segment separating the circle of radius Rₘₐₓ from a ring of the circle of radius Rₘᵢₙ, from its largest adjacent ring. Advantageously, said length L is the minimum length that separates them, satisfying the following relation: L=Pₐ−CD. The bridge interconnects (8) have widths preferably equivalent to the width CD of the active photovoltaic regions (2) and are distributed randomly between two adjacent active annuli. Advantageously, the distance d between two bridges connecting two adjacent active annuli is between 200 and 1000 μm in order to optimize the electrical conductivity within the photovoltaic cell.

From this single cell, it is possible to manufacture photovoltaic modules composed of several cells connected in series in order to increase the voltage across the terminals of the photovoltaic module. It is then necessary to create insulating regions within the architecture described in FIG. 3A.

FIG. 3B is an example of such an architecture of a photovoltaic module known in the state of the art. Insulation lines (41) have been added to the diagram of FIG. 3A to form four photovoltaic cells whose active surfaces are equal. In this example, the insulation lines (41) are straight lines that are perceptible to the eye because they create a disturbance in the circular symmetry of the architecture of the active photovoltaic regions. All the active photovoltaic annuli (2) are intersected by insulating regions (4) into four active annulus arcs (14) of the same active surface, therefore of the same length. Thus, between two adjacent active annuli (2), all the insulating regions (4) face one another in a radial direction to form the four clearly visible insulation lines (41), which is problematic.

FIG. 3C is a diagram of a photovoltaic module architecture according to the invention, containing aligned insulation lines (42) making it possible to create four photovoltaic cells whose active surfaces are equal. Compared to FIG. 3B, the invention therefore consists in modifying the placement of the insulating regions (4) so that two insulating regions (4) belonging to two adjacent active annuli (2) never face one another. A possible example of insulation lines has been shown by the dotted path (42). In this type of architecture, the non-linear insulation lines (42) are no longer perceptible, while maintaining four photovoltaic cells connected in series.

Such an architecture can be obtained by the arrangement method explained below. Said method of arranging active photovoltaic regions and their interconnections is described for a semi-transparent module with four cells connected in series. In this method, the cells are formed by ring arcs interconnected by bridges. Each cell is therefore a succession of ring arcs, the mean radius R of which varies according to a constant pitch Pₐ. For a given radius, the four ring arcs with the same mean radius R have the same area (equal arc lengths and constant width CD).

The steps of the algorithm making it possible to design a possible structure of the photovoltaic module according to the invention are described below.

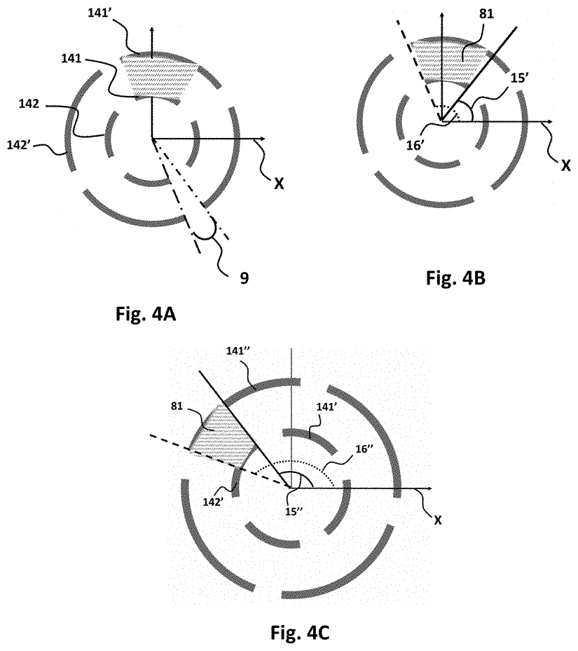

To simplify their reading, the architectures shown schematically in FIGS. 4A and 4B are exactly the same. Only what is annotated therein differs from one figure to another.

FIG. 4C shows a different arrangement of the annulus arcs in comparison with FIGS. 4A and 4B.

### Definition of Parameters:

image resolution (DU);
mean radius (Rₖ), k being the index of the radius, k=1 corresponding to the smallest radius considered;
total number of rings (NB);
constant width (CD) of the rings;
total number of cells (N);
constant inter-arc length (Linter-arc);
length of the arc of radius Rₖ (L_{arc_k});
length of the inter-cell arc of radius Rₖ (L_{inter-cell_k});
number of cell i, such that the first cell has an index i=1;
starting angle (Âd_{i,R_k}) of the arc of index (i,Rₖ);
stopping angle (Âa_{i,R_k}) of the arc of index (i,Rₖ);
pitch of the grating (P_{a,k}): P_{a,k}=Rₖ₊₁−Rₖ, k≥1 considered here as constant and of value (Pₐ);
minimum distance between two bridge interconnects (d).
   By convention, the angles are measured according to trigonometric convention.
   Step 0: Create a working file or image.
   Step 1: Choose the initial parameters:
image resolution (DU);
smallest dimension of the active photovoltaic regions, corresponding to the width of the ring arcs (CD);
number of cells (N);
number of rings (NB);
inter-arc length defined as the length of the insulating arcs (Linter-arc);
mean radius (R₁) of the active annulus of index 1;
mean radius (R_{NB}) of the active annulus of index NB;
pitch of the grating (Pₐ) of the annulus network;
minimum distance between two bridge interconnects (d).
   Step 2: Calculate the length of the arcs for any integer k ranging from 1 to NB. An arc of index (i,Rₖ) is defined by its mean radius (Rₖ), its width (CD), its starting angle (Âd_{i,R_k}), its arc length (L_{arc_k}). The arc length is calculated according to the formula: L_{arc_k}=L_{inter-cell_k}−L_{inter-arc}=(2πR_{K}/N)−L_{inter-arc}. In this particular case, the arcs of a circle with the same mean radius have the same length.

By convention, in the remainder of the document, for a given mean radius R, the index i=1 is reserved for the ring arc whose starting angle Âd has the smallest value. The index i=2 is reserved for the ring arc that has the second smallest starting angle value. The method will be repeated to assign the following indices in the same way. For example, within FIG. 4A are shown:
the arc (141) of index (1,R₁) of the active annulus of mean radius R₁;
the arc (142) of index (2,R₁) of the active annulus of mean radius R₁;
the arc (141′) of index (1,R₂) of the active annulus of mean radius R₂;
the arc (142′) of index (2,R₂) of the active annulus of mean radius R₂.
   In this particular example, the arc (141) of index (1,R₁) faces the arc (141′) of index (1,R₂).
   Step 3: Calculate the starting angles Âd_{i,R_k} for any integer k ranging from 1 to NB and any integer i ranging from 1 to N.
   Âd_{i,R_k} is an angle whose value is chosen randomly between 0 and 2π/N characterized in that (Âd_{i,R_k}≠Âd_{i,R_k-1}) and (Âd_{i,R_k}≠Âd_{i,R_k+1}) for k>1. Secondary arcs refer to the arcs of rings resulting from the starting angles Âd_{i+1,R_k} such that i>1. The starting angles of the secondary arcs are calculated according to:

Âd_{i,R_k;}=Âd_{i-1,Rk}+(2π/N)*(i−1) for i>1.

FIG. 4B shows the starting angle Âd_{1,1} (15′) of the arc (141) of index (1,R₁).
Step 4: Calculate stopping angles Âa_{i,R_k} for any integer k ranging from 1 to NB and any integer i ranging from 1 to N.

Let θₖ be the angle associated with the inter-arc length associated with the ring of mean radius Rₖ. This angle is defined by the relation: θₖ=L_{inter_arc}/Rₖ. The stopping angle of the trace of the arc of index (i,Rₖ) is calculated according to the formula: Âa_{i,R_k}=Âd_{i+1,R_k}−θₖ.

An example of an inter-arc angle θ₂ (9) of mean radius R₂ is shown in FIG. 4A, while the stopping angle Âa_{1,R_1} (16′) of the arc (141) of index (1,R₁) is shown in FIG. 4B.

Step 5: Trace ring arcs for any integer k ranging from 1 to NB and any integer i ranging from 1 to N.

The traces of the ring arcs of index (i,Rₖ) are done by considering the mean radius Rₖ as well as the width CD of the rings. The tracing begins for example from the starting angle Âd_{i,R_k} and ends by considering the stopping angle Âa_{i,R_k}. Those skilled in the art will be able to trace these ring arcs by other methods using the parameters described above (starting angle, stopping angle, arc lengths, mean radius, maximum radius, minimum radius). Not all of the traces are therefore described here.

Step 6: Determine the placement bounds of the bridge interconnects.

To form a cell, it is necessary to connect, step by step, an annulus arc of mean radius Rₖ to an annulus arc of mean radius Rₖ₊₁, for k ranging from 1 to NB. In order to electrically optimize the cell, it is imperative to maximize the number of bridge interconnects. In order to achieve this condition, the choice of annulus arcs to be connected must be optimized. For example, the annulus arc of mean radius Rₖ and index 1 can be connected to the arc of circle of radius Rₖ₊₁ but of index 2. To find this optimization, one solution is to:
Set the interval I₁ by I₁=[Âd_{1,R_k+1}, Âa_{1,R_k+1}]
Find, among the Âd_{i,R_k} and Âa_{i,R_k} (for i varying from 1 to N), all the values that belong to the interval I₁. Âₘᵢₙ denotes the smallest of these values and Âₘₐₓ the largest.
   If Âₘᵢₙ and Âₘₐₓ have the same index i, they are the two bounds delimiting the placement of the bridge interconnects.
   Otherwise, we find the index i of the arc of radius Rₖ and the two bounds of the maximum difference Â_{diff} such that Â_{diff}=max((Âₘᵢₙ−Âd_{1,R_k+1}), (Âa_{1,R_k+1}−Âₘₐₓ)). This index i therefore defines the arc of circle of radius Rₖ that optimizes the maximum of bridge interconnects between the arc of circle of radius Rₖ₊₁ and index 1, and the arc of circle of radius Rₖ and index i. The two bounds of the difference (Âₘᵢₙ and Âd_{1,R_k+1}) or (Âa_{1,R_k+1} and Âₘₐₓ) are the two bounds delimiting the placement of the bridge interconnects.
      To illustrate this step, a first example is given below based on the diagrams of FIGS. 4A and 4B.
The interval I₁ is defined by the starting Âd_{1,R_2} and stopping Âa_{1,R_2} angles (not shown) of the arc (141′), such that I₁=[Âd_{1,R_2}, Âa_{1,R_2}].
Among the starting and stopping angles of radii R₁, we find the values of the starting and stopping angles as they belong to the interval I₁. Âₘᵢₙ corresponds to the starting angle Âd_{1,R_1} (15′) and Âₘₐₓ corresponds to the stopping angle Âa_{1,R1} (16′). Âₘᵢₙ and Âₘₐₓ belong to the same arc of circle of index (1,R₁). They therefore correspond to the two bounds delimiting the placement region (81) of the bridge interconnects.
   Alternatively, a second example is described based on the diagram of FIG. 4C. In this figure, only the values of interest are shown to improve readability.
The interval I₁ is defined by the starting Âd_{1,R_2} (not shown) and stopping Âa_{1,R_2} (16″) angles of the arc (141″) such that I₁=[Âd_{1,R_2}, Âa_{1,R_2}].
We find again, among the starting and stopping angles of rays R₁, the values of the starting and stopping angles as they belong to the interval I₁. Âₘᵢₙ corresponds to the stopping angle Âa_{1,R_1} (not shown) and Âₘₐₓ corresponds to the starting angle Âd_{2,R_1} (15″). Âₘᵢₙ belongs to the arc of index 1,R_1 and Âₘₐₓ belongs to the arc of index 2,R_1. Âₘᵢₙ and Âₘₐₓ therefore do not belong to the same arc of circle.
In this case, we find the index i of the arc of radius such that Â_{diff}=max((Âₘᵢₙ−Âd_{1,R_2}), (Âa_{1,R_2}−Âₘₐₓ))=(Âa_{1,R_2}−Âd_{2,R_1}). The index i is therefore the index 2. The placement region (81) is delimited by the angles Âa_{1,R_2} (16″) and Âd_{2,R_1} (15″). In order to optimize the number and the placement of the bridge interconnects, the cell 1 will be composed of the arc (141″) of index (2,R₁) and of the arc (142′) of index (1,R₂). This operation is repeated between all the arcs of the rings to find the locations of each batch of bridge interconnects.
   Step 8: Place bridge interconnects.

The bridge interconnects of width CD are placed between the bounds defined in step 7 so that the distance d between two bridge interconnects is at least equal to the pitch Pₐ. Advantageously, so that the density of bridges is not visible, the inter-bridge distance (d) is at least equal to ten times the value of the pitch Pₐ.

In particular, it is advantageous to place these bridges randomly. To this end, an angle Âa_{ai_1} between the two bounds defined in step 7 is randomly found, and the first bridge interconnect is placed between the two arcs of circles defined by said bounds. We can repeat the step of finding a random angle from one of the bounds and the angle Âa_{ai_1} previously calculated. If the desired angle satisfies the inter-bridge distance condition (d), the bridge interconnect is placed at this angle. The operation is repeated, and it stops when it is no longer possible to place bridges.

Nomenclature used for the description of all the figures:

| | |
|---|---|
| 1 | Annulus |
| 11 | Interior line of the annulus |
| 12 | Exterior line of the annulus |
| R12 | Line equidistant from the interior and exterior line |
| 13 | Central point |
| 14 | Annulus arc |
| 141, 141′, 141″ | Annulus arc of index i = 1 |
| 142, 142′, 142″ | Annulus arc of index i = 2 |
| 15, 15′, 15″ | Starting angle Âd |
| 15A | Starting ray |
| 15B | First end of the annulus arc |
| 16, 16′, 16″ | Stopping angle Âd |
| 16A | Stopping ray |
| 16B | Second end of the annulus arc |
| 2 | Active region |
| 3 | Vacant space |
| 4 | Insulating region |
| 41 | Linear insulation line |
| 42 | Non-linear insulation line |
| 5 | Semi-transparent module |
| 6 | Bus location |
| 6A | Front contact bus |
| 6B | Rear contact bus |
| 7 | Shade linked to a watch flange |
| 8 | Bridge interconnect |
| 81 | Bridge interconnect placement region |
| 9 | Inter-arc angle |

### Example Embodiment

The method that is the object of the invention can be implemented by considering a photovoltaic module based on amorphous silicon deposited on a glass substrate. The electrodes consist of a transparent conductive oxide on the front face and aluminum on the rear face. The stack of thin layers making up said photovoltaic module is protected by a transparent encapsulation material. Semi-transparency is achieved either by local and selective laser ablation of the material or by standard photolithography methods. The initial parameters for the design are as follows:
The resolution of the image is fixed at 1 nm;
The photovoltaic width of the arcs of circles is 20 μm;
The number of cells is 4;
The number of circles is 373;
The inter-arc length is 10 μm;
The smallest radius is 100 μm;
The largest radius is 15 μm;
The pitch of the grating is 40 μm;
The minimum distance between two bridge interconnects is 1000 μm.

1. A semi-transparent photovoltaic module including a plurality of photovoltaic cells electrically connected in series, said cells comprising:
active photovoltaic regions contained in annulus arcs of active annuli, said active photovoltaic regions of the same active annulus being separated by insulating regions;
vacant spaces forming transparent regions between active regions and arranged in transparent annuli;
two adjacent active annuli in a radial direction being separated by a transparent annulus and two active photovoltaic regions of adjacent active annuli in a radial direction belonging to the same cell being connected by at least one conductive bridge interconnect;
wherein the insulating regions of the same photovoltaic cell that are adjacent in a radial direction do not face one another.

2. The module of claim 1, wherein the conductive bridge interconnects do not face one another.

3. The module of claim 1, wherein the insulating regions are transparent.

4. The module of claim 1, wherein the active annuli all have the same geometric shape.

5. The module of claim 1, wherein the active annuli and the transparent annuli are concentric rings.

6. The module of claim 1, wherein the active annuli are radially spaced apart by a constant pitch Pₐ.

7. The module of claim 1, wherein the active annuli all have a constant width.

8. The module of claim 1, wherein the active photovoltaic regions (2) have a constant width.

9. The module of claim 1, wherein the width of the active photovoltaic regions is between 10 nm and 50 μm.

10. The module of claim 1, wherein the width of the concentric rings and the width of the bridge interconnects are of the same order of magnitude.

11. The module of claim 1, wherein the active photovoltaic regions (2) are the same width as the active annuli.

12. The module of claim 1, wherein the bridge interconnects are distributed randomly between two active photovoltaic regions of radially adjacent active annuli belonging to the same cell.

13. The module of claim 1, wherein the total area of all the bridge interconnects does not exceed 10% of the total area of the active photovoltaic regions.
